(19) United States
(12) Patent Application Publication
(10) Pub. No.: US 2002/0192969 A1
(43) Pub. Date: Dec. 19, 2002

(54) Method for etching silicon trenches

(76) Inventor: Becky Losee, Lehi, UT (US)

Correspondence Address: KENNETH E. HORTON, RADER, FISHMAN & GRAUER PLLC, RIVERPARK CORPORATE CENTER ONE, 10653 SOUTH RIVERFRONT PARKWAY, SUITE 150, SOUTH JORDAN, UT, 84095, US

(21) Appl. No.: 09/843,023

(22) Filed: Apr. 26, 2001

(51) Int. Cl. H01L 21/302; H01L 27/108; H01L 21/461; H01L 21/76

(52) U.S. Cl. 438/709; 257/69; 257/302; 438/424

(57) ABSTRACT

An etching process for manufacturing deep trenches in silicon layers of semiconductor devices and the resulting structures is described. The etching process makes the trenches using a chlorine-based chemical as the primary etchant, while employing various additives to obtain the desired trench surface conditions, geometry, shape, and uniformity. The etching process obtains the trenches in a single step, decreasing the cost and time for manufacturing. In the future, as requirements for IC components (i.e., capacitors and deep isolation trenches) using trenches become more restrictive, the method and structures of present invention could become an integral part of trench technology.

### FIELD OF THE INVENTION

The present invention generally relates to methods for fabricating integrated circuits (ICs) and semiconductor devices and the resulting structures. More particularly, the present invention relates to methods for etching a silicon layer to forms trenches having a uniform profile and depth.

### BACKGROUND OF THE INVENTION

There are numerous devices comprising silicon layers containing deep or high aspect ratio trenches. Forming such deep trenches in the silicon layer of these devices provides many novel and promising structures. The types of devices containing such trenches include the numerous types of silicon-based MEMS devices, as well ICs.

In IC fabrication, devices such as transistors may be formed on a semiconductor wafer or substrate, which is typically made of silicon. Deep openings, or trenches, which have high aspect ratios may be etched in the silicon for storage purposes, to form isolated capacitors, in MEMS device applications, or for various other purposes. These trenches can be classified on their depth: openings with depths of about 1 μm to about 10 μm can be classified as deep trenches, whereas depths of more than about 10 μm can be classified as ultra deep openings.

For certain IC applications, such trenches are important to the final structure of the device. Many IC manufacturing processes typically form a plurality of semiconductor devices with a gate, a source, and a drain for field effect transmitter (FET) devices. Other IC manufacturing processes typically form a base, an emitter, and a collector for bipolar devices. For both types of devices, forming and using trenches in the silicon layers are an integral part of the manufacturing process. As well, numerous other types of structures and devices in an IC use such trenches.

Trenches are also becoming important in isolation techniques. For example, one isolation technique uses trench isolation, where the trench is etched and refilled with an insulating material. Refilled trenches have been used in a number of VLSI (very large scale integration) and ULSI (ultra large scale integration) applications. Trench isolation, including etch and refill processing, is becoming an important tool in the fabrication of electronic devices that exploit three dimensional structural concepts.

Trenches can be formed by numerous methods, such as reactive ion etching (RIE) of the silicon layer. The trenches are used to isolate parts of an integrated circuit by completely etching through an epitaxial layer grown on top of a mono-crystalline semiconductor wafer. Insulating layers, such as oxide and nitride layers, protect the epitaxial layer in selected areas that are not etched. See, for example, U.S. Pat. No. 6,103,635, the disclosure of which is incorporated herein by reference.

Presently, plasma systems are used to carry out the RIE of silicon layer to make trenches. The processes provided by the manufacturers of such plasma etching systems often use fluorine-based gas mixtures such as NF₃, HBR, and HeO₂ mixtures or SF₆ and O₂ mixtures as the etching gases. See, for example, U.S. Pat. Nos. 6,069,091 and 6,191,043, as well as A. A. Ayon et al. Mat. Res. Soc. Symp. Proc. 546 (1999) 51-61, Y. X. Li et al. SPIE 2639 (date unknown) 244-252, and A. Burtsev et al. Microelectonics Engineering 40 (1998) 85-97, the disclosures of which are incorporated herein by reference. It is also known to use gas mixtures containing chlorine as the primary etchant gas. See, for example, U.S. Pat. Nos. 6,175,144, 6,180,533, 5,843,226, 6,069,086, and 6,121,154, the disclosures of which are incorporated herein by reference.

Processes containing fluorine-based chemicals as the main etchant, however, do not provide trenches with the necessary quality for a deep trench. FIG. 2 illustrates a trench 13 formed in silicon layer 15 by a typical fluorine-based etching process. As depicted in FIG. 2, the trench is wider at the bottom 23 than at the top 22 of the trench as shown by parallel lines 191. When re-filling the trench with a material, such as a polysilicon fill, this type of trench would cause holes in the material (polysilicon) fill. Although this may not be important in certain instances, it is very important for those trenches used as the basis for other components of an IC, such as a transistor. Further, the trenches often have sharp comers 181 at the opening of the trench. These sharp comers are also undesirable for many components in an IC which use a trench.

Attempts have been made to correct these deficiencies in fluorine-based etching process. FIG. 3 depicts a trench resulting from a process designed to obtain a trench that is wider at the top 22 than the bottom 23 (as shown by parallel lines 192).

Unfortunately, as shown in this Figure, the corners 242 at the bottom of the trench 13 become unacceptable because they become sharp, unlike the rounded comers 241 in FIG. 2. Further, no change has been made to the sharp comers 182.

Chlorine-based etching process for such trenches have also not obtained the desired quality of trenches. FIG. 4 illustrates a trench 13 formed by a typical chlorine-based etching process. Note that the top comers 183 are still undesirably sharp, the bottom comers 243 are undesirably sharp, the bottom of the trench contains spikes, and the sidewalls of the trench are uneven (as shown by parallel lines 193).

It is important to control the trench profile angle, sidewall continuity and smoothness, flatness of the trench bottoms and the shape of the trench bottom comers in order to form trenches which can be employed as high-quality components during IC fabrication. For example, the trench profile angle typically varies from about 75° to about 90°. Generally, as the trench sidewall angle increases toward 90°, it becomes more difficult to fill the trenches with the desired material (i.e., polysilicon) without forming voids. With sidewall angles over 90°, voids typically form in the refill material. With sidewall angles less than 75°, fewer devices can be formed because each device requires a greater area because of the sidewall angle.

As to the shape of the trench top and bottom comers, round comers are highly advantageous to minimize stress related defects and electrical leakage. As well, sharp trench comers do not provide the necessary electrical separation for subsequent layers formed in and over the trench. Further, sharp comers have higher electrical fields than rounded comers. It is also advantageous that the trenches have smooth and continuous sidewalls and flat and clean trench bottom surfaces to maintain integrity of the oxide and improve device performance.

It is also important that uniformity of the trench characteristics exists across the substrate being processed. Profile non-uniformity results when the cross-sectional profile of the trenches vary as a function of the spacing between the features on the substrate. It is desirable that the etch process produce features having uniform characteristics regardless of the distance between the features or the density of the features.

It is also highly desirable to achieve maximum uniformity of the trench depth and the trench sidewall angle across the wafer. Particularly, the trench depth and the sidewall angle should be substantially constant between the center and the edge of the region being processed (i.e., wafer). A uniform trench depth enables uniform device performance across the wafer. In addition, it is highly desirable that the trench sidewall angle be substantially independent of the trench depth, so that the trench depth does not limit the trench profile angle that is achievable in a trench etch process.

Unfortunately, the known processes are inadequate to manufacture deep trenches (1-25 microns) with the desired trench surface conditions, geometry, shape, and uniformity. As well, known trench etch processes are unable to achieve the needs of closely controlling the trench profile angle and the shape of the trench bottom comers, forming smooth and continuous trench sidewalls and flat and clean trench bottom surfaces, in a single etch process.

Thus, there is a need for a single-step process for etching trenches in silicon that exhibit (i) rounded trench bottom comers, (ii) a substantially uniform trench depth across the etching area, (iii) a substantially uniform trench sidewall angle across the etching area, (iv) smooth and continuous trench sidewalls, (v) flat and clean trench bottoms, (vi) rounded comers on the top surface of the trench, and (vii) made with a high throughput to facilitate a manufacturing environment.

### SUMMARY OF THE INVENTION

The present invention provides an etching process for manufacturing deep trenches in silicon layers of semiconductor devices and the resulting structures. The etching process makes the trenches using a chlorine-based chemical as the primary etchant, while employing various additives to obtain the desired trench surface conditions, geometry, shape, and uniformity. The etching process obtains the trenches in a single step, decreasing the cost and time for manufacturing. In the future, as requirements for IC components (i.e., capacitors and deep isolation trenches) using trenches become more restrictive, the method and structures of present invention could become an integral part of trench technology.

### BRIEF DESCRIPTION OF THE DRAWINGS

FIGS. 1a-1b and 2-7 are views of one aspect of the method of making a trench in a silicon layer, and the structure formed in the process, according to the present invention, in which:

FIGS. 1a-1b illustrate the sequence of steps in one aspect of process of the present invention;

FIGS. 2-4 illustrate trenches made according to known processes for etching trenches in silicon;

FIG. 5 illustrates is a schematic view of one apparatus for practicing the method of the present invention;

FIG. 6 illustrates a SEM photograph of a trench formed during one aspect of the process of the present invention; and

FIG. 7 illustrates a SEM photograph of a trench formed during another aspect of the process of the present invention.

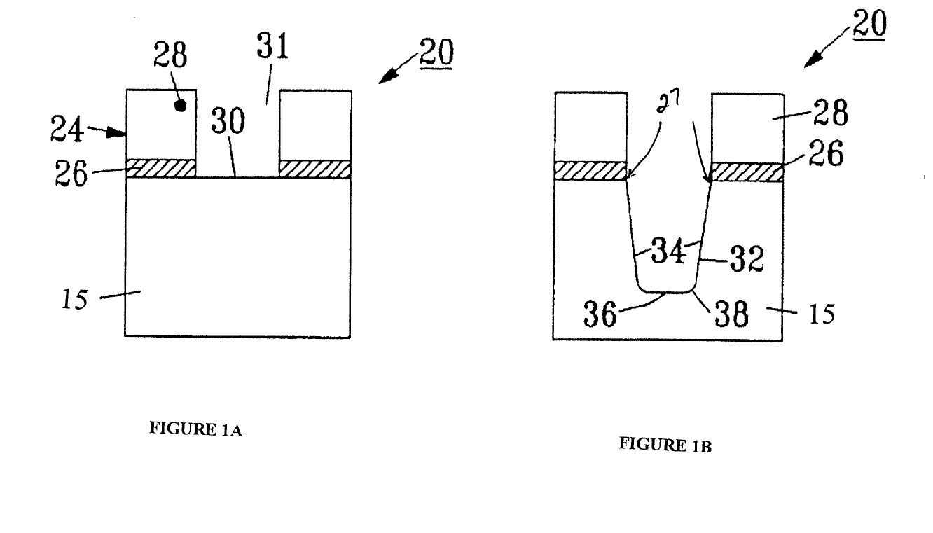

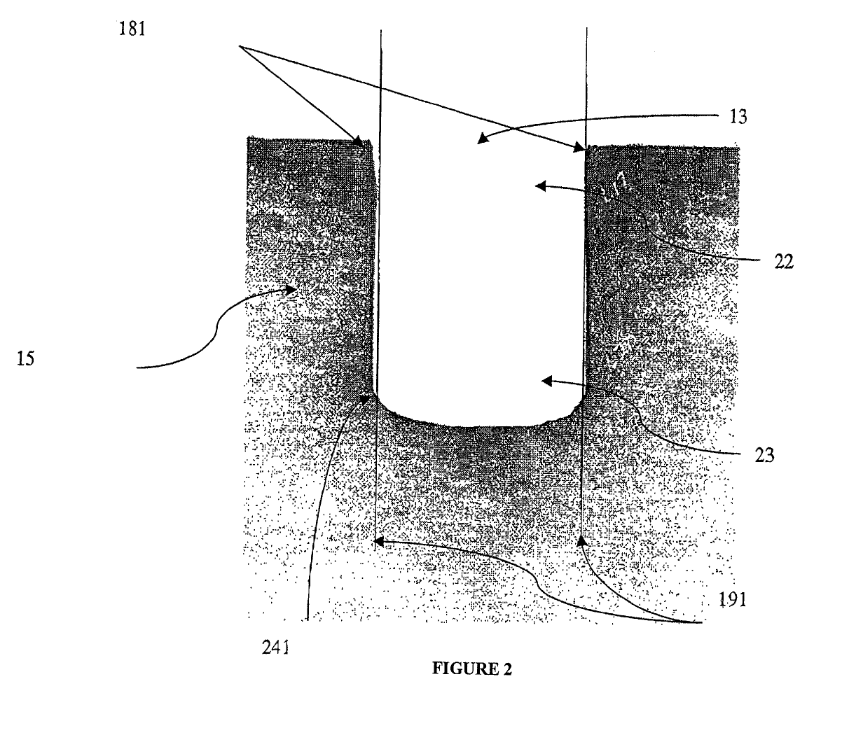

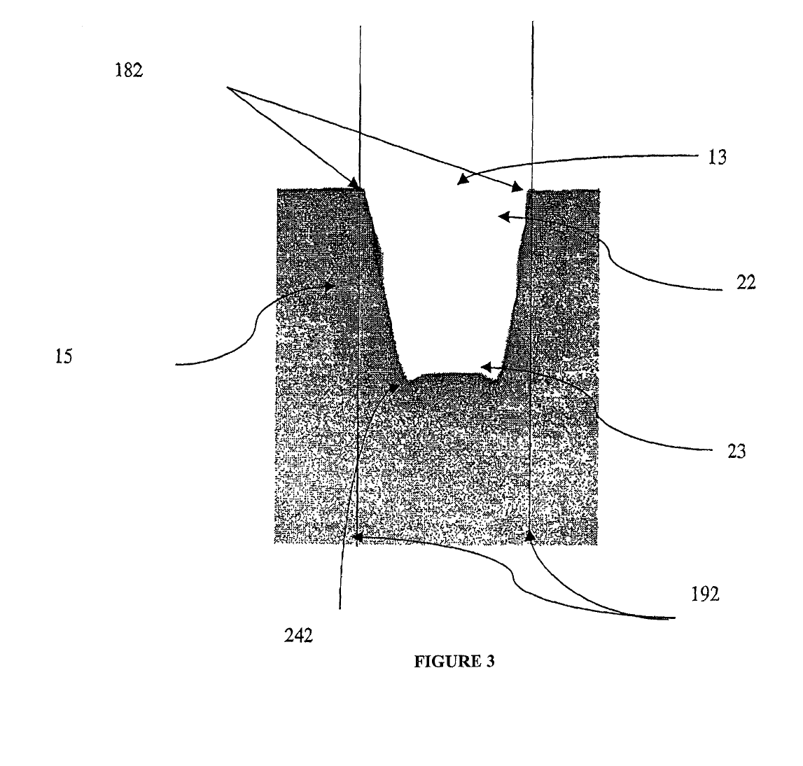

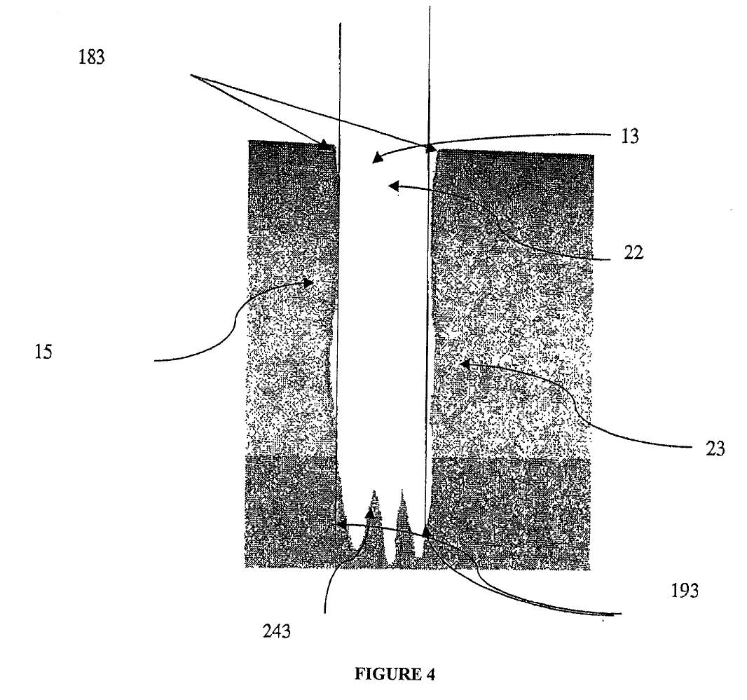

FIGS. 1-7 presented in conjunction with this description are views of only particular—rather than complete—portions of the method for making a trench in a silicon layer and the structure formed during the method.

### DETAILED DESCRIPTION OF THE INVENTION

The following description provides specific details in order to provide a thorough understanding of the present invention. The skilled artisan, however, would understand that the present invention can be practiced without employing these specific details. Indeed, the present invention can be practiced by modifying the illustrated structure and method, and can be used in conjunction with apparatus and techniques conventionally used in the industry. For example, while the present invention is described with reference to semiconductor devices, it could be modified for other types of silicon devices such as silicon-based MEMS.

FIGS. 1a-1b illustrate one aspect of a trench manufacturing process of the present invention. The trenches formed in the present invention can be used in any suitable type of device. Suitable types of devices include those containing a silicon layer-including a silicon layer or a silicon-based layer such as a silicon-germanium layer-such as silicon-based MEMS devices, ICs such as RAM devices, as well as discrete MOSFETS, diodes, capacitors, ink jets, and CMOS devices. Preferably, the trenches are used are ICs and semiconductor devices.

First, device 20 containing a silicon layer 15 with upper surface 30 is provided. Any suitable Si layer can be employed in the present invention. Suitable silicon layers include silicon wafers, epitaxial Si layers, polysilicon layers, bonded wafers such as used in silicon-on-insulator (SOI) technologies, and/or amorphous silicon layers, all of which may be doped or undoped. Preferably, the silicon layer in the present invention is a single crystal silicon wafer which has an epitaxial (“epi”) Si layer provided on an upper surface. The epi Si layer can be provided using any known process in the art, including any known epitaxial deposition process. In one aspect of the invention, a thin native oxide layer can be present between the Si wafer and the epi Si layer.

Next, a mask 24 is provided over the silicon layer 15. Although the mask 24 is illustrated as located on Si layer 15, the mask 24 could also be located over the silicon layer 22, e.g., with intervening layers, films, or other structures. The type and size of mask 24 on the silicon layer 15 can vary depending on the required processing requirements. In one aspect of the present invention, the mask described below is used.

Mask 24 can comprise either a single layer or multiple layers as known in the art. See, for example, U.S. Pat. Nos. 6,103,635 and 6,121,154, the disclosures of which are incorporated herein by reference. In one preferred aspect of the invention, mask 24 comprises a two-layer structure: first layer 26 and second layer 28. The first layer 26 is provided on upper surface 30 of the silicon layer 15. The first layer can, for example, comprise a layer of a nitride material—such as Si₃N₄ having an underlying SiO₂ pad oxide layer (not shown)-on the upper surface 30 of the silicon layer 15. In another aspect of the invention, the first layer 26 is an oxide layer with a thickness thick enough so that it will not be etched away during subsequent etching but thin enough such that the desired trench geometries can be achieved. The second layer 28 is located over the layer 26. Second layer 28 can comprise, for example, any suitable photoresist material. The thickness and other characteristics of the first and second layer are well known and can be optimized as known in the art. An exemplary mask 24, including materials and thicknesses, is described in U.S. Pat. No. 6,103,635, the disclosure of which is incorporated herein by reference.

Optionally, mask 24 can further comprise an organic antireflective coating to reduce reflective notching standing waves and back scattered light, maximize photoresist exposure latitude, and optimize photoresist sidewall profiles during the photolithography process. The optional antireflective coating can be located as any desired location in mask 24, such as between the first and second layers. Numerous organic antireflective coatings are commercially available and can be employed in the present invention.

Mask 24 contains a pattern of openings 31 that expose the surface of silicon layer 15. The pattern of openings generally correspond to the locations where the trenches will be formed. To form the openings, the photoresist layer 28 is patterned during a photolithographic process as known in the art. The patterning process removes portions of the photoresist layer in the location of openings 31. With these portions of the photoresist layer 28 removed, the underlying portion of the first layer 26 (near openings 31) are removed using a conventional etching process known in the art. The remaining portions of the photoresist can be optionally removed at this stage using any process known in the art. See, for example, U.S. Pat. No. 6,103,635, the disclosure of which is incorporated herein by reference.

With openings 31 formed in mask 24, the trench 32 is then formed in silicon layer 15 via a chlorine-based etching process as depicted in FIG. 1b. The trench 32 includes opposed sidewalls 34, a trench bottom 36, top comers 27, and trench bottom comers 38. The trenches typically have a minimum width of from about 0.1 micron to about 25 microns. In one aspect of the invention, the trench width can range from about 0.25 micron up to about 2 microns. Preferably, the width of the trenches ranges from about 0.4 micron to about 1.5 microns.

While the desired depth to which the trenches are etched depends on many factors, the depth primarily depends on the desired device characteristics using the trench. In one aspect of the invention, the depth of the trench exceeds the depth of the silicon layer 15. For example, when the silicon layer 15 comprises an epi Si layer on a Si wafer, the depth of the trench should be greater than the thickness of the epi Si layer, thus intruding into the Si wafer. In this example, if desired, the trench could even be greater than the epi Si layer and the Si wafer combined, thereby creating a channel from the upper surface of the epi Si layer through bottom side of the Si wafer.

Generally, the trenches of the present invention have a depth of from about 1 micron to about 25 microns. Preferably, the depth of the trenches range from about 1 micron to about 20 microns. More preferably, the depth of the trenches can range from about 1.2 microns to about 5 microns. Even more preferably, the depth of the trench can range from about 1.25 microns to about 2.2 microns.

The profile of the trenches is an important characteristic of the trenches in the present invention. The trenches should have a suitable profile (sidewall) angle, rounded bottom and top comers (i.e., no sharp comers), and smooth and continuous sidewalls. The sidewall angle of the trenches in the present invention can be any angle that aids and/or does not impede further processing for devices using the trench. For example, when re-filling the trench with polysilicon, the trench angle should not be greater than about 90° because of difficulties in uniform re-fill of the trench. As well, the angles should be as close as possible to 90° because this allows the maximum number of trenches to be formed within a given area. Thus, the profile angle can range from about 75° to about 90°. Preferably, the profile angle ranges from about 88° to about 89°.

Although not necessary, a preliminary etching process can be used to etch through any native oxide layer present on silicon layer 15. The preliminary etch is performed only to remove native oxide thickness ranging up to about 35 Å from the surface of the silicon layer 15. Preferably, the growth of such native oxide thickness has been prevented, or the characteristics of the native oxide layer are such a preliminary etch is not necessary. Any suitable etching process for removing the native oxide layers can be employed in the present invention. For example, an exemplary etching process for this preliminary etch step uses CF₄.

The trenches of the present invention are formed in silicon layer 15 by any suitable etching process known in the art. The etching process begins by forming upper sidewall portions in the silicon layer 15. The process then continues to produce lower sidewall portions and rounded bottom corners 38. The parameters of the etching process are controlled to preferably form round bottom corners, smooth and continuous sidewalls, and flat and clean trench bottom surfaces 36, thereby maintaining the integrity of the device characteristics using the trenches. If the photoresist layer 23 has not been removed prior to this etching step, the etching process can be configured to remove the photoresist material while forming the trenches.

After forming the trenches, the mask 24 is removed by any suitable process known in the art. When present, the photoresist layer 28 can be removed from the layer 26 using a conventional stripping solution such as H₂SO₄/H₂O₂ or an O₂ ash. The layer 26 (comprising the nitride and pad oxide) can then be removed by wet chemical etching. Following removal of mask 24, the silicon layer can be dipped in a diluted acidic solution to remove any passivation present on the sidewalls 34. Further cleaning can be performed as known in the art.

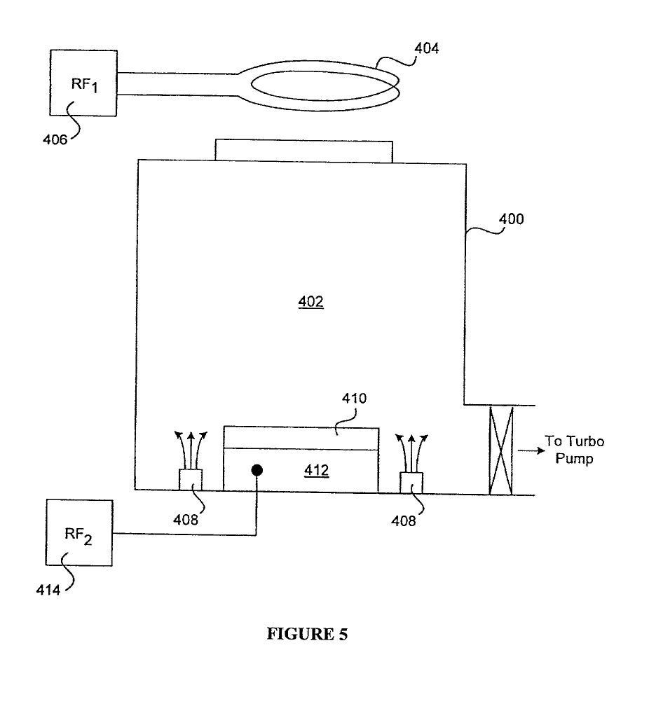

The etching process is carried out in any suitable etching apparatus known in the art. A suitable etching apparatus is any apparatus that is able to create a highly-uniform etching action across the entire region where the chemical and/or physical etching of the silicon is occurring. See, for example, U.S. Pat. Nos. 6,069,086, 5,935,874, and 6,188,564, the disclosures of which are incorporated herein by reference. Another example of a suitable apparatus is a plasma reactor, such as the plasma reactor illustrated in FIG. 5. Preferably, the plasma reactor creates a uniform gaseous plasma in the area where etching occurs. The more uniform the plasma, the more uniform the trench characteristics across the region of etching.

FIG. 5 illustrates a simplified schematic of a plasma reactor 400, including a plasma processing chamber 402. Above chamber 402, there is disposed an electrode 404, which is implemented by an induction coil or other suitable induction means. Coil 404 represents the plasma generation source and is energized by a RF generator 406 via a matching network (not shown). The RF power supplied to coil 404 may have an RF frequency of, for example, 13.56 MHz. Provided in chamber 402 is a gas distribution plate 408, which preferably includes a plurality of holes for distributing gaseous source materials, e.g., the etchant source gases, into the RF-induced plasma region between itself and substrate 410 containing the silicon layer 15 to be etched. The gaseous source materials may also be released from ports built into the walls of the chamber itself or from another gas distribution arrangement such as a shower head arrangement above the substrate. Substrate 410 is introduced into chamber 402 and disposed on a chuck 412, which acts as the bottom electrode and is preferably biased by a radio frequency generator 414 (also typically via a matching network). The RF energy supplied by RF generator 414 controls, in part, the ion energy of the plasma. Chuck 412 may be any suitable work piece holder and may be implemented by, for example, an electrostatic (ESC) chuck, a mechanical-type chuck, a vacuum chuck, and the like.

In operation, the plasma reactor 400 provides a plasma in the processing chamber 402. Preferably, the plasma is a high density plasma, such as a plasma having an ion density greater than about 10¹¹/10¹² ions per cm³. In contrast, medium or low density plasma have a density below about 10¹¹/10¹² ions per cm³. Preferably, the plasma reactor permits independent control of the plasma generation source and the ion energy source to control the plasma density and the plasma ion energy independently.

The plasma reactor is operated in the following manner. The substrate 410 with silicon layer 15 such as shown in FIG. 1a is placed on church 412 and an etchant gas mixture is introduced through the gas inlet 408 into the plasma processing chamber 402. A plasma is generated from the process gas in an etch zone 54, near silicon layer 15. While the different gases in the etchant gas mixture can be mixed in the reaction chamber, they are preferably mixed upstream of the reaction chamber 402 before entering. A plasma is struck from the etchant gas mixture and the gaseous plasma is then utilized to etch trenches in the silicon layer 15. The etch is terminated when the desired trench depth is reached, either after a predefined time period or by monitoring the trench depth during etching.

The process gas used in the etch process for etching the silicon layer 15 comprises any suitable etching gas mixture known in the art that will yield the desired trench properties. In one aspect of the invention, the etchant gas mixture contains a chlorine-containing gas. Any suitable chlorine-containing gas could be employed, depending on the trench characteristics, the other gases in the etchant mixture, the etch rate, surface smoothness, and profile. In one aspect of the invention, the chlorine-containing gas is Cl₂.

The etchant gas mixture also contains a gas for passivation purposes. The passivation additive gas acts to passivate the trench sidewalls for control of the profile angle and the trench width. Any known gas or mixture of gases which achieves such a function can be employed in the present invention. In one aspect of the invention, the passivation additive gas is HBr or N₂. Preferably, HBr is used as the passivating gas.

The etchant gas mixture also contains an additive gas(es) for selectivity purposes. The selectivity additive gas aids the passivation described above by diminishing the side attack of the etchant, thereby maintaining the correct width and profile. Any known gas which achieves such a function can be employed in the present invention, such as oxygen. In one aspect of the invention, oxygen is used as the selectivity gas additive. The oxygen is preferably in the form of O₂.

Thus, the ratio of the passivation additive gas(es) and the selectivity additive gas(es) should be controlled carefully to obtain the desired width and profile of the trench. In a preferred aspect of the invention, HBr and O₂ are used together as the passivation additive and the selectivity additive. The combination of these two gases forms a silicon-based bromine passivation layer that is oxidized by the oxygen, thereby diminishing (and even preventing) the side etch and maintaining the desired width and profile of the trench. The relative amount of these two gases are discusses below.

The etchant gas mixture further comprises any suitable diluent gas whose ions force the primary etchant (Cl₂) to the bottom of the trench, thereby yielding rounded comers. Absent the diluent gas, the plasma field will drive the Cl₂ ions, but the diluent gas is important to obtain the rounded comers. Suitable diluent gases include any gas accomplishing this purpose, like the “inert” gases such as Ne, Ar, Kr, Xe, and Rn. As well, the diluent gas includes any “non-reactive” gas—a gas which does not interact with the silicon or otherwise react with the etchant gaseous mixture-such as He and N. Preferably, the heavier (molecular weight) diluent gases are employed in the present invention. More preferably, Ar is used as the diluent gas in the etchant gas mixture. Without being restricted to this explanation, it is believed that the diluent gas becomes a plasma and, therefore, becomes more than merely a chemically-inert gas. The flow of the diluent gas is important as it has a effect on the corners of the trench, especially the bottom comers.

The amount and composition of the etchant gas mixture can be varied by adjusting the total flow rate of the mixture, as well as the relative amount of each component. The total flow rate of the etchant gas depends on the size of the region to be etched, the desired etch rate, and the total amount of open area per wafer. In one aspect of the invention, the total flow rate can range from about 75 sccm to about 425 sccm. Preferably, the total flow rate is about 227 sccm.

The flow rate of the chlorine-containing gas depends on the actual gas employed, the desired etch rate, and the other gases used in the etchant gas mixture. For example, when Cl₂ is employed as the chlorine-containing gas, the flow rate can range from about 25 to about 100 sccm, and preferably the flow rate is about 75 sccm.

The flow rate of the passivating gas depends on the actual gas employed, the desired etch rate, and the other gases used in the etchant gas mixture. For example, when HBr is employed as the passivating gas, the flow rate can range from about 25 to about 200 sccm, and preferably the flow rate is about 100 sccm.

The flow rate of the selectivity gas depends on the actual gas employed, the desired etch rate, and the other gases used in the etchant gas mixture. For example, when O₂ is employed as the selectivity gas, the flow rate can range up to about 4 sccm, and preferably the flow rate is about 2 sccm.

The flow rate of the diluent gas depends on the actual gas employed, the desired etch rate, and the other gases used in the etchant gas mixture. For example, when Ar is employed as the diluent gas, the flow rate can range from about 20 to about 125 sccm, and preferably the flow rate is about 50 sccm.

Several of the operating parameters of the plasma reactor are important in obtaining the trench characteristics mentioned above. One of these operating parameters is the power used to generate the plasma. The RF power of the bottom plate (or the bias power) depends on the desired etching rate: generally the higher the RF power, the higher the etching rate. In one aspect of the present invention, this RF power generally ranges from about 1 Watt to about 400 Watts. More preferably, the bias power ranges from about 100 to about 400 Watts, and is more preferably about 300 watts.

The RF power of the top plate in the plasma reactor differs from the power of the bottom plate. In one aspect of the present invention, the RF power of the top plate ranges from about 400 to about 650 watts. Preferably, this RF power is about 500 watts.

The pressure in the plasma reactor is also an important parameter to control. The pressure used depends on the etchant gas mixture, gas flow rates, profile, and across depth uniformity. The pressure in the reactor should be maintained from about 5 mTorr to about 80 mTorr, and preferably is about 30 mTorr.

The process of the present invention achieves a high degree of uniformity of the silicon layer 15. In the present invention, “uniformity” refers to the variation of the properties of the trenches across the area or region being etched. One of the problems with previous etching processes is that the trench properties were not substantially uniform across the surface being etched, leading to portions of the surface (including underlying areas have been previously processed) being discarded. For example, in one known process described in U.S. Pat. No. 5,843,226, the uniformity of the trench characteristics was about 3% across the etching region. In certain instances, as much as 40-60% of the surface (and underlying wafer) are discarded due to non-uniformity of the trench properties.

In one aspect of the invention, the present invention achieves a high uniformity of the trench depth. The trench depth uniformity will depend primarily on the depth of the trenches, but will also depend slightly on the mask size and the size of the area in which the trenches are formed. The trench depth uniformity in the present invention is less than about 500 angstroms and preferably ranges from about 50 angstroms to about 500 angstroms. The trench depth uniformity in the present invention is less than about 2%. Preferably, the trench depth uniformity is less than about 0.5%. More preferably, the trench depth uniformity in the present invention is less than about 0.1%. For example, a six-inch diameter silicon layer was etched as above with a trench depth of 1.5 microns. The total variation in trench depth was measured to be within 0.03 microns. Thus, the trench depth uniformity was 1.5±0.015 microns or a uniformity of about 2%.

The present invention achieves a high uniformity of the profile (or sidewall) angle. Unlike many of the known processes, the sidewall angle uniformity does not depend on the depth of the trenches. The sidewall angle uniformity is less than about 0.5% and is preferably less than about 0.2%. More preferably, the profile angle uniformity is less than about 0.15%. For example, a six-inch diameter silicon layer was etched as above for a sidewall angle of 89°. The total variation in profile angle was measured to be within 1°. Thus, the sidewall angle uniformity was 89°±0.5° or a uniformity of about 0.5%. Indeed, by carefully controlling the parameters of the etching process, there is substantial uniformity in the sidewall angle.

Once formed by the above process, the trenches can be used to form any known component in the semiconductor device. In one aspect of the invention, the trenches can be used in silicon-based MEMS devices. See, for example, A. A. Ayon et al. Mat. Res. Soc. Symp. Proc. Vol. 546 (1999) 51-61 and Y. X. Li et al. SPIE Vol. 2639 (date unknown) 244-252, the disclosures of which are incorporated herein by reference. In another aspect of the invention, the trenches can be used to form isolation regions, as described in U.S. Pat. No. 6,175,144, the disclosure of which is incorporated herein by reference. In another aspect of the invention, the trenches can be used to form capacitors, as described in U.S. Pat. No. 6,103,635, the disclosure of which is incorporated herein by reference. In yet another aspect of the invention, the trenches can be used to form vertical transistors as known in the art

The following non-limiting examples illustrate the present invention.

### EXAMPLE 1

A six-inch diameter single-crystal wafer was obtained. The surface was cleaned and prepared, and an epitaxial silicon layer was then grown on the silicon wafer surface by standard processing. Next, a 1600 angstrom thermal oxide layer is grown on the epitaxial silicon layer by standard processing. A photoresist layer was then deposited, patterned, and developed by standard processing. The exposed portions of the thermal oxide layer are then removed by an oxide plasma etch.

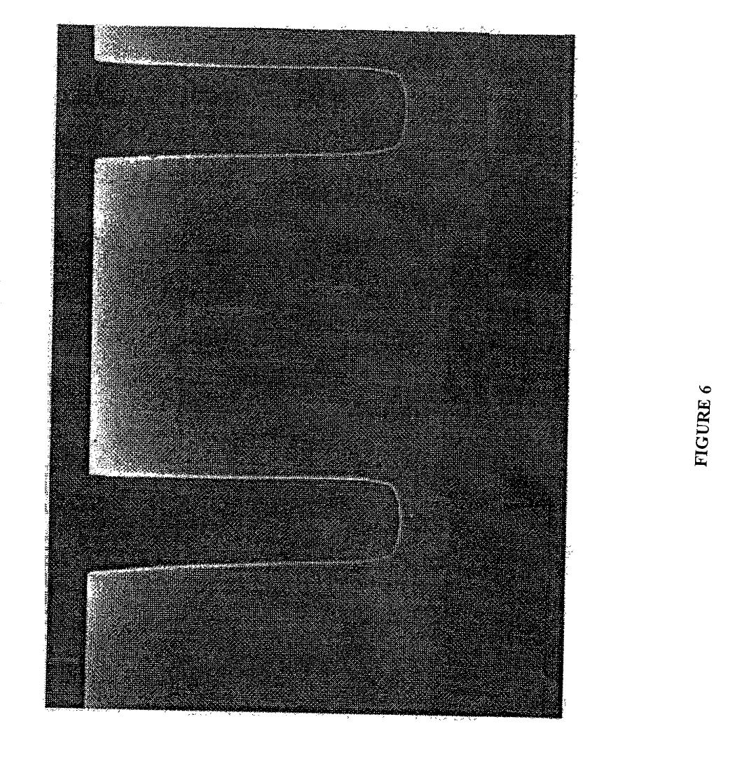

The trenches are then etched in the epitaxial silicon layer using the thermal oxide as a mask during the etching process. The trenches are etched using a gaseous mixture of Cl₂ of 75 sccm, HBr of 100 sccm, O₂ of 2 sccm, and Ar of 50 sccm in a plasma chamber with an RF bottom power of 350 watts, a top RF power of 500 watts, and a pressure of 30 millitorr. The etching procedure is continued for 110 seconds until a trench depth of 1.5 microns and a depth uniformity of 0.004 microns is obtained. A SEM photograph of the resulting trench is depicted in FIG. 6.

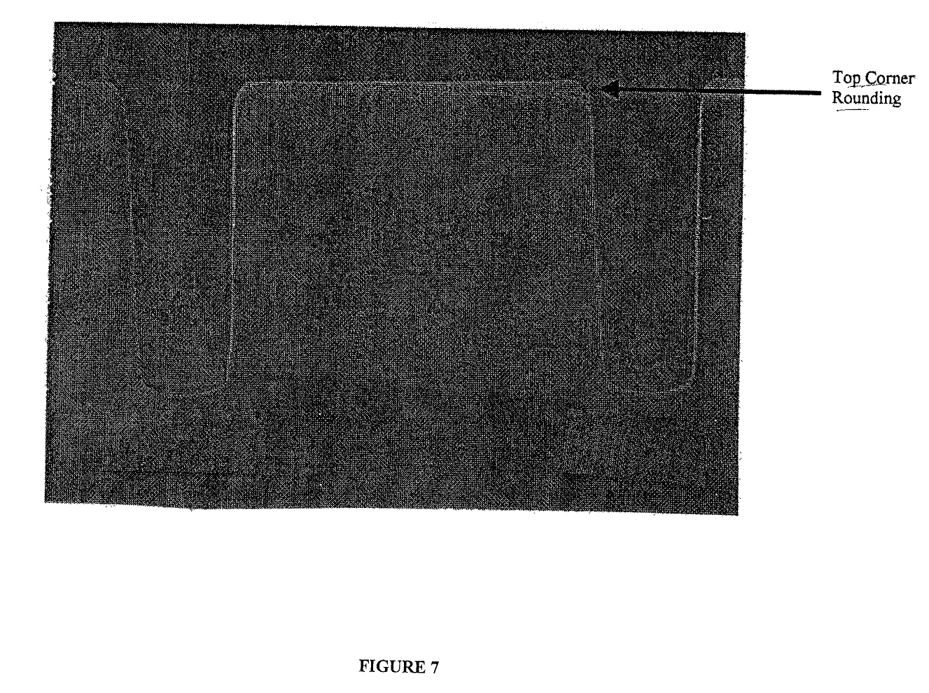

During the etch process, a sidewall passivation forms on the upper sidewalls of the trench. A buffered oxide wet etch is performed to remove the sidewall passivation on the sidewalls and the oxide mask. A SEM photograph of the resulting trench is depicted in FIG. 7.

Five regions of the epitaxial silicon layer are selected in which to measure the trench depth: a middle region and four peripheral regions. The depth and sidewall angle of the trenches in these five regions are measured and reported in Table 1. As seen in Table 1, the trenches have an extremely high uniformity of trench depth and sidewall angle.

TABLE 1

| | Area 1 | Area 2 | Area 3 | Area 4 | Area 5 |
|---|---|---|---|---|---|
| Trench | 1.49 | 1.52 | 1.51 | 1.50 | 1.51 |
| Depth | | | | | |
| Profile | 89 | 90 | 89 | 89 | 89 |
| Angle | | | | | |

### EXAMPLE 2

The process of Example 1 was repeated, except that the Cl₂-based etching procedure was performed for 127 seconds to obtain a trench depth of 1.7 microns. Five regions of the epitaxial silicon layer are selected in which to measure the trench depth: a middle region and four peripheral regions. The depth and sidewall angle of the trenches in these five regions are measured and reported in Table 2. As seen in Table 2, the trenches have an extremely high uniformity of trench depth and sidewall angle.

TABLE 2

| | Area 1 | Area 2 | Area 3 | Area 4 | Area 5 |
|---|---|---|---|---|---|
| Trench | 1.69 | 1.74 | 1.74 | 1.74 | 1.73 |
| Depth | | | | | |
| Profile | 89 | 89 | 89 | 89 | 89 |
| Angle | | | | | |

### EXAMPLE 3

The process of Example 1 was repeated, except that the Cl₂-based etching procedure was performed for 90 seconds to obtain a trench depth of about 1.0 microns. Five regions of the epitaxial silicon layer are selected in which to measure the trench depth: a middle region and four peripheral regions. The depth and sidewall angle of the trenches in these five regions are measured and reported in Table 3. As seen in Table 3, the trenches have an extremely high uniformity of trench depth and sidewall angle.

TABLE 3

| | Area 1 | Area 2 | Area 3 | Area 4 | Area 5 |
|---|---|---|---|---|---|
| Trench | 1.03 | 1.02 | 1.023 | 1.04 | 1.02 |
| Depth | | | | | |
| Profile | 89 | 89 | 89 | 89 | 89 |
| Angle | | | | | |

Having described the preferred embodiments of the present invention, it is understood that the invention defined by the appended claims is not to be limited by particular details set forth in the above description, as many apparent variations thereof are possible without departing from the spirit or scope thereof.

I claim:

1. A method for making a deep trench in a silicon layer, comprising:
providing a silicon layer;
providing a patterned mask over the silicon layer;
etching the silicon layer with a plasma gas comprising a Cl₂, HBr, O₂, and Ar; and
removing the patterned mask.

2. The method of claim 1, wherein the deep trench has a depth ranging from about 1.25 microns to about 20 microns.

3. The method of claim 1, wherein the deep trench has a depth ranging from about 1.5 microns to about 5 microns.

4. A method for making a trench in a silicon layer, comprising:
providing a silicon layer;
providing a patterned mask over the silicon layer;
etching the silicon layer with a uniform plasma gas comprising a chlorine-containing gas, a passivating gas, a selectivity gas, and a diluent gas; and
removing the patterned mask.

5. The method of claim 4, wherein the chlorine-containing gas comprises Cl₂.

6. The method of claim 4, wherein the passivating gas comprises HBr.

7. The method of claim 4, wherein the selectivity gas is O₂.

8. The method of claim 4, wherein the diluent gas is Ar.

9. The method of claim 4, wherein the uniform gas plasma etches a plurality of trenches with a substantially uniform depth.

10. The method of claim 4, wherein the etching is performed in a single step.

11. A method for making a plurality of trenches in silicon layer, comprising:
providing a silicon layer;
providing a mask over the silicon layer;
etching the silicon layer with a gas mixture comprising a chlorine-containing gas to make a plurality of trenches; and
removing the patterned mask;
the plurality of trenches having a depth uniformity of less than about 2%.

12. The method of claim 11, wherein the depth uniformity is less than about 0.5%.

13. The method of claim 11, wherein the variance in trench depth is less than about 500 angstroms.

14. The method of claim 11, wherein the variance in trench depth ranges from about 50 to about 500 angstroms.

15. The method of claim 11, wherein the depth uniformity is independent of the width of the plurality of trenches.

16. A method for making a plurality of trenches in silicon layer, comprising:
providing a silicon layer;
providing a mask over the silicon layer;
etching the silicon layer with a gas mixture comprising a chlorine-containing gas to make a plurality of trenches; and
removing the patterned mask;
the plurality of trenches having a sidewall angle uniformity of less than about 0.5%.

17. The method of claim 16, wherein the plurality of trenches has substantially the same sidewall angle.

18. The method of claim 16, wherein the sidewall angle uniformity of less than about 0.15%.

19. The method of claim 16, wherein the sidewall angle is about 89°.

20. A method for making a plurality of trenches in a silicon layer, comprising:
providing a silicon layer;
providing a patterned mask over the silicon layer;
etching the silicon layer with a uniform plasma gas comprising a Cl₂, HBr, O₂, and Ar; and
removing the patterned mask;
the plurality of trenches having a depth ranging from about 1.5 to about 25 microns and a depth uniformity of less than about 2%.

21. A method for making a semiconductor device containing a deep trench in a silicon layer, comprising:
providing a silicon layer;
providing a patterned mask over the silicon layer;
etching the silicon layer with a plasma gas comprising a Cl₂, HBr, O₂, and Ar; and removing the patterned mask.

22. A method for making a semiconductor device containing a trench in a silicon layer, comprising:
providing a silicon layer;
providing a patterned mask over the silicon layer;
etching the silicon layer with a uniform plasma gas comprising a chlorine-containing gas, a passivating gas, a selectivity gas, and a diluent gas; and
removing the patterned mask.

23. A method for making a semiconductor device containing a plurality of trenches in a silicon layer, comprising:
providing a silicon layer;
providing a mask over the silicon layer;
etching the silicon layer with a gas mixture comprising a chlorine-containing gas to make a plurality of trenches; and
removing the patterned mask;
the plurality of trenches having a depth uniformity of less than about 2%.

24. A method for making semiconductor device containing a plurality of trenches in a silicon layer, comprising:
providing a silicon layer;
providing a mask over the silicon layer;
etching the silicon layer with a gas mixture comprising a chlorine-containing gas to make a plurality of trenches; and
removing the patterned mask;
the plurality of trenches having a sidewall angle uniformity of less than about 0.5%.

25. A deep trench in a silicon layer made by the method comprising:
providing a silicon layer;
providing a patterned mask over the silicon layer;
etching the silicon layer with a plasma gas comprising a Cl₂, HBr, O₂, and Ar; and
removing the patterned mask.

26. A trench in a silicon layer made by the method comprising:
providing a silicon layer;
providing a patterned mask over the silicon layer;
etching the silicon layer with a uniform plasma gas comprising a chlorine-containing gas, a passivating gas, a selectivity gas, and a diluent gas; and
removing the patterned mask.

27. A plurality of trenches in a silicon layer made by the method comprising:
providing a silicon layer;
providing a mask over the silicon layer;
etching the silicon layer with a gas mixture comprising a chlorine-containing gas to make a plurality of trenches; and
removing the patterned mask;
the plurality of trenches having a depth uniformity of less than about 2%.

28. A plurality of trenches in a silicon layer made by the method comprising:
providing a silicon layer;
providing a mask over the silicon layer;
etching the silicon layer with a gas mixture comprising a chlorine-containing gas to make a plurality of trenches; and
removing the patterned mask;
the plurality of trenches having a sidewall angle uniformity of less than about 0.5%.

29. A semiconductor device containing a deep trench in a silicon layer made by the method comprising:
providing a silicon layer;
providing a patterned mask over the silicon layer;
etching the silicon layer with a plasma gas comprising a Cl₂, HBr, O₂, and Ar; and removing the patterned mask.

30. A semiconductor device containing a trench in a silicon layer made by the method comprising:
providing a silicon layer;
providing a patterned mask over the silicon layer;
etching the silicon layer with a uniform plasma gas comprising a chlorine-containing gas, a passivating gas, a selectivity gas, and a diluent gas; and
removing the patterned mask.

31. A semiconductor device containing a plurality of trenches in a silicon layer made by the method comprising:
providing a silicon layer;
providing a mask over the silicon layer;
etching the silicon layer with a gas mixture comprising a chlorine-containing gas to make a plurality of trenches; and
removing the patterned mask;
the plurality of trenches having a depth uniformity of less than about 2%.

32. A semiconductor device containing a plurality of trenches in a silicon layer made by the method comprising:
providing a silicon layer;
providing a mask over the silicon layer;
etching the silicon layer with a gas mixture comprising a chlorine-containing gas to make a plurality of trenches; and
removing the patterned mask;
the plurality of trenches having a sidewall angle uniformity of less than about 0.5%.

33. A silicon layer containing a plurality of trenches, wherein the plurality of trenches has a depth uniformity of less than about 2%.

34. The silicon layer of claim 33, wherein the variance in trench depths is up to about 500 angstroms.

35. The silicon layer of claim 33, wherein the depth uniformity is independent of the width of the plurality of trenches.

36. A silicon layer containing a plurality trenches, wherein the plurality of trenches has a sidewall angle uniformity of less than about 0.5%.

37. The silicon layer of claim 36, wherein the plurality of trenches has substantially the same sidewall angle.

38. A plurality of trenches in a silicon layer, wherein the plurality of trenches has a depth uniformity of less than about 2%.

39. The plurality of trenches of claim 38, wherein the variance in trench depths is up to about 500 angstroms.

40. The plurality of trenches of claim 38, wherein the depth uniformity is independent of the width of the plurality of trenches.

41. A plurality of trenches in a silicon layer, wherein the plurality of trenches has a sidewall angle uniformity of less than about 0.5%.

42. The plurality of trenches of claim 41, wherein the plurality of trenches has substantially the same sidewall angle.

43. A semiconductor device containing plurality of trenches in a silicon layer, wherein the plurality of trenches has a depth uniformity of less than about 2%.

44. The semiconductor device of claim 43, wherein the variance in trench depths is up to about 500 angstroms.

45. The semiconductor device of claim 43, wherein the depth uniformity is independent of the width of the plurality of trenches.

46. A semiconductor device containing plurality of trenches in a silicon layer, wherein the plurality of trenches has a sidewall angle uniformity of less than about 0.5%.

47. The semiconductor device of claim 41, wherein the plurality of trenches has substantially the same sidewall angle.

48. A semiconductor device containing plurality of vertical transistors in a silicon layer, wherein the plurality of vertical transistors has a depth uniformity of less than about 2%.

49. A semiconductor device containing plurality of vertical transistors in a silicon layer, wherein the plurality of vertical transistors has a sidewall angle uniformity of less than about 0.5%.

50. A plurality of vertical transistors in a silicon layer, wherein the plurality of transistors has a depth uniformity of less than about 2%.

51. A plurality of vertical transistors in a silicon layer, wherein the plurality of transistors has a sidewall angle uniformity of less than about 0.5%.
